(19) United States
(12) Patent Application Publication
(10) Pub. No.: US 2007/0189881 A1
(43) Pub. Date: Aug. 16, 2007

(54) Positioning member and stand for supporting holder

(75) Inventors: Shunichi Imao, Tokyo (JP); Toshihiko Aoki, Tokyo (JP); Akihiko Kosugi, Tokyo (JP); Yoshitaka Inui, Minato-ku (JP)

Correspondence Address: KOLISCH HARTWELL, P.C., 200 PACIFIC BUILDING, 520 SW YAMHILL STREET, PORTLAND, OR, 97204, US

(73) Assignees: Sumco Corporation, Minato-ku (JP); Daifuku Co., Ltd., Osaka-shi (JP)

(21) Appl. No.: 11/351,541

(22) Filed: Feb. 10, 2006

(51) Int. Cl. H01L 21/677

(52) U.S. Cl. 414/217.1

(57) ABSTRACT

A positioning member for placing a substrate transporting holder on a supporting stand, which member is provided on the side of the supporting stand and is removably insertable into a slotted guide recess formed on a bottom surface of the substrate transporting holder. The positioning member has a stainless steel body composed of a cylindrical shaft and a pointed guide formed on top of the shaft; and a film formed by the co-deposition of polyfluoroethylene and nickel on a surface of the body.

### BACKGROUND OF THE INVENTION

1. Field of the Invention

The present invention relates to a positioning member used when supporting a holder at a predetermined position, and to a holder supporting stand having such a positioning member.

2. Description of Related Art

When semiconductor substrates such as silicon wafers are manufactured, the manufacturing process passes through numerous production steps. Because semiconductor substrates under production are sensitive to dust, they are generally transported between the respective production steps within a substrate transporting holder.

Automatic transport vehicles are used to reduce the labor involved in transporting such substrate transporting holders. Supporting stands for transferring substrate transporting holders between automatic transport vehicles or to and from other handling equipment are thus provided within the semiconductor plant.

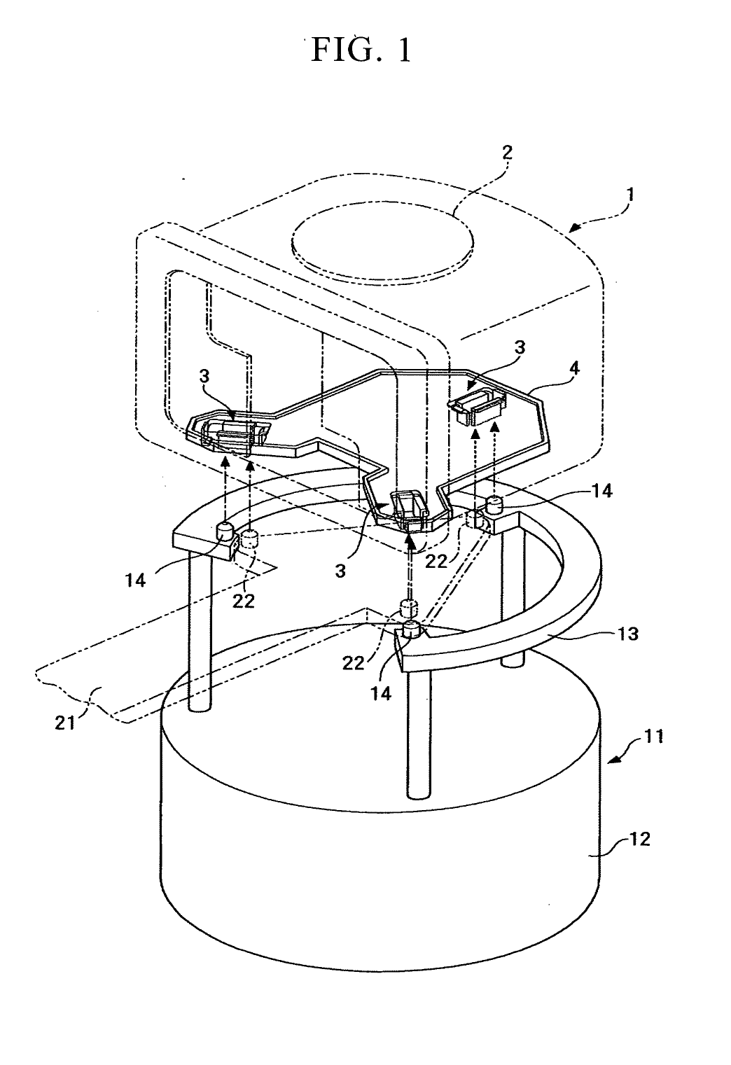

To reliably carry out the transfer of a holder, such a supporting stand is provided with a holder positioning member. Pin-like projections that are removably insertable into slotted recesses formed on the bottom side (base) of the holder have hitherto been used as this positioning member (see, for example, Patent Reference 1).
Patent Reference 1: Japanese Unexamined Patent Application, First Publication No. 2000-223552 (see FIG. 1).

Transfer of the substrate transporting holder is carried out automatically by a transfer device provided on an automatic transport apparatus or as a manual operation by a worker. The positioning member provided on the supporting stand is made of stainless steel to extend its life. However, in cases where transfer is performed manually by a worker, to enable smooth insertion of the positioning members into the recesses, use may conceivably be made of slippery-surfaced polyfluoroethylene, for example, as the material making up the positioning members.

When transfer of the substrate transporting holder is carried out with a transfer device, because the recesses in the holder are precisely guided onto the positioning members, use of the more durable stainless steel does not pose a problem. However, when such transfer is performed manually by a worker, because precise positioning cannot be carried out, the positioning members inevitably rub frequently against the sides of the recesses. Under the circumstances, if the positioning members are made of polyfluoroethylene, the durability to wear decreases. Moreover, because dust generated by such wear adheres to the sides of the positioning members on account of static electricity, complete removal with an air cleaning system has been difficult to achieve. In a silicon wafer manufacturing system, it is particularly critical to minimize dust generation.

The present invention was conceived in light of such problems with the prior art. The object of the invention is to provide, at least when manually placing a substrate transporting holder on a supporting stand, a positioning member which is smoothly insertable into a recess provided on the bottom side of the holder and is capable of inhibiting dust generation, and a holder-supporting stand on which such positioning members are provided.

### SUMMARY OF THE INVENTION

In a first aspect, the present invention provides a positioning member for placing a holder on a supporting stand, which member is provided on the side of the supporting stand and is removably insertable into a guide recess formed on a bottom surface of the holder. The positioning member includes a stainless steel body (a positioning member body which is made of stainless steel) having a cylindrical shaft and a pointed guide formed on top of the shaft; and a film formed by the co-deposition of polyfluoroethylene and nickel on a surface of the body.

In a second aspect, the present invention provides a positioning member according to the first aspect in which the guide has an outside shape that is conical or spherical.

It is especially preferable to use the positioning member of the present invention at least when manually placing the holder on the supporting stand.

In a third aspect, the present invention provides a stand which is equipped with positioning members according to the first aspect and is adapted for supporting a holder that is made of plastic and has guide recesses in a plurality of places on a bottom surface thereof, wherein the positioning members according to the first aspect are individually disposed at positions corresponding to the guide recesses provided in a plurality of places on the bottom surface of the holder.

In a fourth aspect, the invention provides a stand which is equipped with positioning members according to the second aspect and is adapted for supporting a holder that is made of plastic and has guide recesses in a plurality of places on a bottom surface thereof, wherein the positioning members according to the second aspect are individually disposed at positions corresponding to the guide recesses provided in a plurality of places on the bottom surface of the holder.

In the holder supporting stand according to the third or fourth aspect of the present invention, it is preferable for three guide recesses to be formed in the bottom surface of the plastic holder, and for a positioning member according to the first or second aspect to be disposed at each position corresponding to the respective guide recesses provided in a plurality of places on the bottom surface of the holder.

The holder supporting stand of the present invention may be one which is provided with an inventive positioning member at a position corresponding to the guide recess provided on the base of a plastic holder having a single guide recess.

In fifth and sixth aspects, the invention provides a holder supporting stand according to the third or fourth aspect of the invention wherein the body of the positioning member is electrically grounded.

Owing to the configuration of the positioning member and the holder supporting stand of the present invention, when a worker manually sets a holder on a holder supporting stand, the positioning members are inserted into the guide recesses on the holder side while coming into contact with the guide recesses. Because a film has been formed on a surface of the positioning member by the co-deposition of polyfluoroethylene and nickel, insertion into the guide recesses is smoothly carried out at this time. In addition, given that nickel has been co-deposited in this film, the positioning member has a better wear resistance than when polyfluoroethylene is used alone, resulting in an extended life.

Also, contact between the plastic guide recesses and the plastic positioning members during the holder positioning operation generates static electricity, but because the positioning member body is made of stainless steel and is electrically grounded, this static electricity is externally discharged and thereby removed. Because this prevents dust adhesion, airborne dust and dust generated by contact between the positioning members and the guide recesses is smoothly aspirated by the air cleaning system provided at the plant, enabling the degree of cleanliness within the plant to be maintained.

### BRIEF DESCRIPTION OF THE DIAGRAMS

FIG. 1 is a schematic perspective view of a positioning member and a stand for supporting a substrate transporting holder according to an embodiment of the present invention.

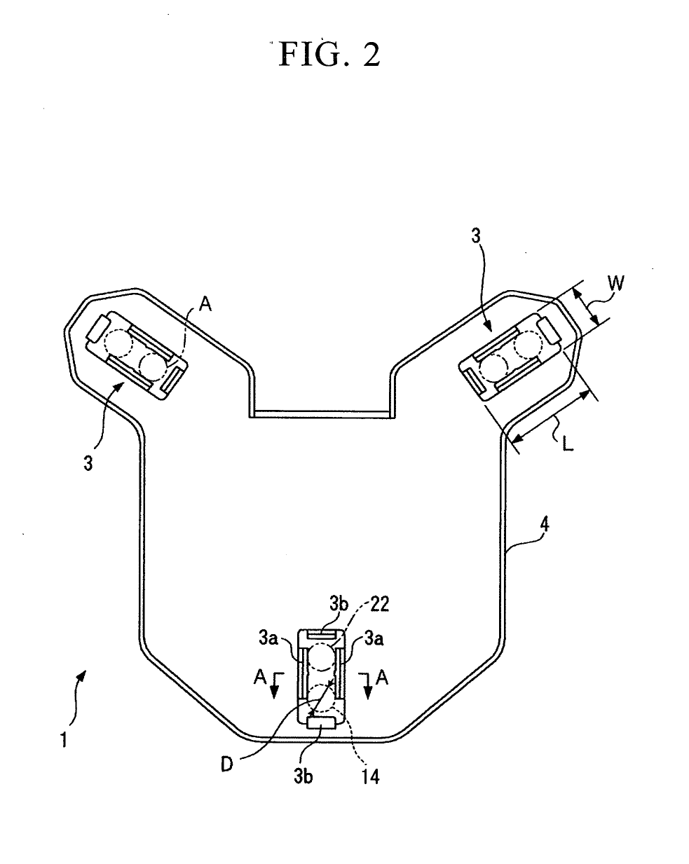

FIG. 2 is a bottom view of the substrate transporting holder shown in FIG. 1.

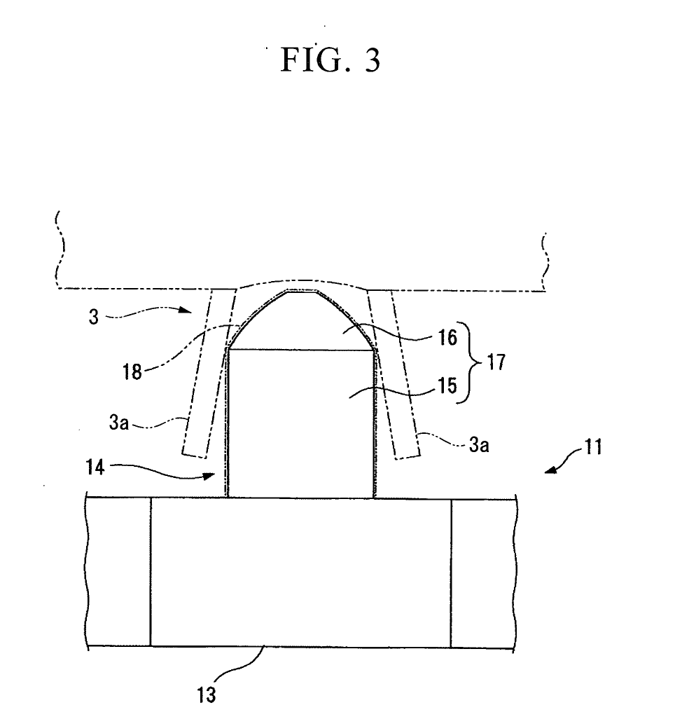

FIG. 3 is a view taken along arrows A-A in FIG. 2.

### DETAILED DESCRIPTION OF THE INVENTION

Embodiments of the positioning member and the holder supporting stand according to the present invention are described below.

The positioning member and the holder supporting stand according to these embodiments are described below in conjunction with FIGS. 1 to 3.

The holder described in the present embodiment is a wafer transporting holder used to carry silicon wafers in an airtight state between various given production steps within a silicon wafer manufacturing system. This holder is adapted for holding and transporting a plurality of disk-shaped silicon wafers at one time.

Automatic transport vehicles are used to automate the transport of wafer transporting holders in this manufacturing system. Holder-supporting stands for transferring a wafer transporting holder to and from an automatic transport vehicle are provided at predetermined positions within the manufacturing plant. In addition, positioning members which are provided on the side of such a holder supporting stand cooperate with other positioning elements provided on the bottom surface of a wafer transporting holder to carry out positioning of the wafer transporting holder.

The wafer transporting holder and the positioning members are described more fully below.

As shown in FIGS. 1 and 2, the wafer transporting holder (referred to below as the “holder”) 1, which is made of a plastic such as polycarbonate, is provided on a top surface thereof with a disk-shaped mechanically engaging projection 2 which engages with and disengages from a holding tool suspended from an overhead traveling automatic transport vehicle (not shown; referred to below as a “stransport vehicle”), and serves to store and transport silicon wafers which are under production (referred to below as “articles”). This holder 1 has on a bottom surface (base) thereof, three equally spaced apart (at 120 degree intervals) and radially oriented slotted guide recesses 3 which serve as other positioning elements capable of guiding and receiving the positioning members. These guide recesses 3 are formed on a mounting plate 4. The same plastic (e.g., polycarbonate) as that making up the holder 1 is used also for the guide recesses 3, i.e., the mounting plate 4.

The supporting stand 11 is composed of a support 12, a horseshoe-shaped mounting portion 13 standing upright on the support 12, and positioning members 14 which stand upright on a top surface of this mounting position 13 and are disposed at 120 degree intervals at positions on, for example, a circle of a predetermined radius. The positions of, or intervals between, these positioning members 14 are the same as the intervals between the guide recesses 3 provided on the side of the holder 1. Three positioning members 14 are provided in this embodiment. However, the positioning members 14 are not limited to three, and may number one or a plurality of two or more in accordance with the number of guide recesses 3 provided on the side of the holder 1.

As shown in FIG. 3, each of the positioning members 14 has a positioning member body 17 composed of a cylindrical shaft 15 and a guide 16 with a gradually narrowing tip formed on top of the shaft 15; and also has a film 18 formed on the surface of the positioning member body 17. Stainless steel (e.g., SUS 304, SUS 430) is used as the material making up the positioning member body 17. The film 18 is formed by the co-deposition of polyfluoroethylene (PTFE) on the surface of this positioning member body 17. This film 18 has a thickness which is in a range of 5 to 20 μm, and preferably is about 10 μm . Following film formation, heat treatment is carried out by heating at about 400° C. The positioning member bodies 17 are electrically grounded so as to remove static electricity generated, for example, when the positioning members 14 are inserted and come into contact with the guide recesses 3.

The guide 16 has a surface shape that is in the form of a truncated cone with only a little of the top cut off and is at the same time also spherical with the sides swelled out slightly (of course, the guide itself may be given a spherical shape; the aim here is to make the guide pointed so that it is easily guided into the guide recess).

Next, the slotted guide recesses 3 provided in the bottom surface of the holder 1 is described.

As shown in FIGS. 2 and 3, these guide recesses 3 are provided so as to correspond to the positions of the three positioning members 14 provided on the supporting stand 11 side. The primary guide mechanism at each of these guide recesses 3 is composed of two sidewalls 3a, 3a provided so as to project from the bottom surface of the holder 1 at a splayed angle therebetween (i.e., two side walls 3a, 3a which project out and are provided so as to be close together near the bottom surface of the holder 1 and become increasingly separated away from the bottom surface of the holder 1) and front and back end walls 3b, 3b. Of course, the width W of the opening at the bottom end of these guide recesses 3 is made wider than the width (diameter) D of the positioning members 14, the width W of the opening at the top end of these guide recesses 3 is made narrower than the width (diameter) D of the positioning members 14, and the length L is made so as to accept, for example, two positioning members 14 (i.e., made longer than 2×D) within the guide recess 3.

A guide recess 3 projecting from the mounting plate 4 is schematically shown in FIG. 3. A positioning member 14 on the supporting stand 11 is inserted into a circumferentially outer portion of each guide recess 3, and a positioning member 22 provided on a holding tool when holding is carried out by a transferring device (or a handling device) provided on the transport vehicle is adapted so as to be insertable into a circumferentially inner portion of each guide recess 3 once the positioning member 14 on the supporting stand 11 has been inserted.

Moreover, as noted above, the positioning members 14 have a film 18 formed on the surface, which film 18 is formed by the co-deposition of polyfluoroethylene and nickel (i.e., the deposition of each of the two ingredients from a solid solution). The positioning members 14 thus smoothly insert into the guide recesses 3 owing to the slipperiness of the polyfluoroethylene, and an excellent wear resistance can be achieved on account of the strength of the nickel.

A holder 1 transferring operation is described in which the positioning members and holder supporting stand configured as described above are used.

First, when a holder 1 that has been placed on the side of the transport vehicle is to be supported on the supporting stand 11, a holding tool 21 at the transferring device on the transport vehicle side moves the holder 1 to the top surface of the supporting stand 11 and to a position where the guide recesses 3 at the bottom surface of the holder 1 correspond to the positioning members 14 provided on the supporting stand 11 side. The holder 1 is then lowered onto the supporting stand 11 by the holding tool 21, thereby inserting the positioning members 14 into the guide recesses 3 and positioning the holder 1 at a predetermined position on the supporting stand 11. In cases where the holder 1 is transported to another place using, for example, a different transport vehicle, by inserting the positioning members 22 provided on the end of the holding tool 21 at the transferring device on the transport vehicle side into the circumferentially inner portions of the respective guide recesses 3 on the holder 1 and raising the holding tool 21, the holder 1 is lifted up from the supporting stand 11 and transported to the other place.

When the holder 1 is automatically placed on the supporting stand 11 by the transferring device on the transport vehicle side, because the positioning operation is carried out very precisely, insertion of the positioning members 14 into the guide recesses is performed smoothly.

By contrast, when the holder 1 is manually placed on the supporting stand 11 by a worker, insertion at a precision of the same order as when the placement operation is carried out automatically with a holding tool on the transferring device is impossible. Hence, during such insertion of the positioning members 14 into the guide recesses 3, the guides 16 on the respective positioning members 14 generally come into contact with both the left and right side walls 3a, 3a (or the end walls 3b, 3b) which form the guide recesses 3 on the bottom surface of the holder 1. A film 18 forms on the surface of the positioning members 14 from the co-deposition of polyfluoroethylene and nickel, enabling the positioning members 14 to be more smoothly guided into the guide recesses 3. In addition, because nickel has been co-deposited in this film 18, the film has a better wear resistance than when it is made only of polyfluoroethylene, thus providing a longer working life.

During the holder 1 positioning operation, static electricity is generated due to contact between the plastic guide recesses 3 and the plastic positioning members 14. However, because each positioning member body 17 is made of stainless steel and is electrically grounded, this static electricity is discharged to the exterior and thereby removed.

The elimination of static electricity prevents plastic dust from adhering to the positioning members 14. As a result, airborne dust and dust generated by contact of the positioning members 14 with the guide recesses 3 is smoothly aspirated by an air cleaning system provided at the manufacturing plant, enabling a good degree of cleanliness to be maintained within the plant.

Although the holder is described in the foregoing embodiment as housing semiconductor devices such as silicon wafers, the above description applies equally well to holders which store other articles and to supporting stands for such holders.

Some preferred embodiments of the invention have been described above, although these embodiments are to be considered in all respects as illustrative and not limitative. Those skilled in the art will appreciate that various additions, deletions, substitutions and other modifications are possible without departing from the spirit of the invention. It is therefore to be understood that the invention may be practiced otherwise than as specifically described without departing from the scope of the appended claims.

What is claimed is:

1. A positioning member for placing a holder on a supporting stand, which member is provided on the side of the supporting stand and is removably insertable into a guide recess formed on a bottom surface of the holder, comprising:
a stainless steel body having a cylindrical shaft and a pointed guide formed on top of the shaft; and
a film formed by the co-deposition of polyfluoroethylene and nickel on a surface of the stainless steel body.

2. The positioning member according to claim 1, wherein the pointed guide has an outside shape which is conical or spherical.

3. A stand which is equipped with positioning members according to claim 1 and is adapted for supporting a holder that is made of plastic and has guide recesses in a plurality of places on a bottom surface thereof,
wherein the positioning members according to claim 1 are individually disposed at positions corresponding to the guide recesses provided in a plurality of places on the bottom surface of the holder.

4. A stand which is equipped with positioning members according to claim 2 and is adapted for supporting a holder that is made of plastic and has guide recesses in a plurality of places on a bottom surface thereof,
wherein the positioning members according to claim 2 are individually disposed at positions corresponding to the guide recesses provided in a plurality of places on the bottom surface of the holder.

5. The stand according to claim 3, wherein the stainless steel body is electrically grounded.

6. The stand according to claim 4, wherein the stainless steel body is electrically grounded.
